(19) United States
(12) Patent Application Publication
(10) Pub. No.: US 2017/0214214 A1
(43) Pub. Date: Jul. 27, 2017

(54) HYBRID SEMICONDUCTOR LASER ABSENT A TOP SEMICONDUCTOR CLADDING LAYER

(71) Applicant: The Board of Regents of the University of Oklahoma, Norman, OK (US)

(72) Inventor: Rui Qing Yang, Norman, OK (US)

(73) Assignee: The Board of Regents of the University of Oklahoma, Norman, OK (US)

(21) Appl. No.: 14/262,326

(22) Filed: Apr. 25, 2014

Related U.S. Application Data
(60) Provisional application No. 61/816,008, filed on Apr. 25, 2013.

(51) Int. Cl. H01S 5/026; H01S 5/042

(52) U.S. Cl. CPC H01S 5/026; H01S 5/042

(57) ABSTRACT

In at least one embodiment, a semiconductor laser is constructed to have a waveguide core including an active region, a top cladding, and a bottom cladding. The top cladding is positioned above the waveguide core and comprises a dielectric layer and a metal layer and optionally a thin semiconductor contact layer. In at least one embodiment of the semiconductor laser, the top cladding is absent a semiconductor material which is able to contain at least 1% of an optical wave that is generated within the waveguide core.

### CROSS REFERENCE TO RELATED APPLICATIONS/INCORPORATION BY REFERENCE STATEMENT

The present patent application incorporates by reference the entire provisional patent application identified by U.S. Ser. No. 61/816,008, filed on Apr. 25, 2013, and claims priority thereto under 35 U.S.C. 119(e).

### STATEMENT REGARDING FEDERALLY SPONSORED RESEARCH OR DEVELOPMENT

This invention was made with government support under Contract Number ECCS1002202 awarded by the National Science Foundation (NSF). The government has certain rights in the invention.

### BACKGROUND

Because of their low threshold current, interband cascade (IC) lasers are emerging as efficient mid-infrared (IR) laser sources for low-threshold power consumption applications (e.g. <0.1 W) in continuous wave (cw) operation at room temperature. In the past, Interband Cascade (IC) lasers have been grown on GaSb substrates with efforts focusing mainly on the 3-4 μm wavelength region, where there are hydrocarbon signatures important for sensing applications. By employing plasmon-waveguide structures, the spectral coverage of IC lasers can be further extended to the long-wavelength IR region. In these long-wavelength IC lasers, the cladding layer becomes thicker and the waveguide loss may increase significantly, presenting challenges for the material growth and difficulty in achieving high device performance. Even with the relative immaturity of the antimonide-based material system, including an incomplete understanding of the best practices for epitaxial growth and device fabrication/packaging, IC lasers on GaSb substrates have exhibited excellent device performance with continuous wave (cw) operation at room temperature and above in the wavelength range from 3-6 μm.

However, the shortcomings of IC lasers on GaSb substrates involve the use of thick (1-5 microns) InAs/AlSb superlattice (SL) cladding layers that typically have more than 2000 interfaces. Creation of such SL layers is very demanding for growth by molecular beam epitaxy (MBE) due to so many shutter movements. Furthermore, an InAs/AlSb SL layer has very low thermal conductivity (κ˜3 W/m·K) and thick SL layers such as are currently used in the field cause significant heating, which limits the output power of IC lasers and may also lead to reliability issues with local strain and thermal stress. The currently used SL cladding layers have a refractive index (˜3.37) that is only slightly smaller than that of the cascade active region (3.43 to 3.47), so the cladding layer must be thick. It is desirable and important to find ways to reduce the cladding layer thickness and suppress the waveguide loss. However, reducing the thickness of the semiconductor cladding layer would lead to substantial leaking of the optical wave into the GaSb substrate (refractive index ˜3.8), resulting in undesirable optical loss. This situation becomes worse when SL cladding layers are used in IC lasers for wavelengths longer than mid-IR because of the requirement of even thicker cladding layers.

The issue of low thermal conductivity is also present in other types of semiconductor lasers that use quaternary semiconductor alloys such as AlGaAsSb as the cladding layer. There is a need to create an IC laser (and other types of semiconductor lasers, particularly in the mid-infrared spectrum) having improved performance in terms of attainable cw output power and reliability, and which could be extended to longer wavelengths.

### BRIEF DESCRIPTION OF THE DRAWINGS

Several embodiments of the presently disclosed inventive concepts are hereby illustrated in the appended drawings. It is to be noted however, that the appended drawings only illustrate several typical embodiments and are therefore not intended to be considered limiting of the scope of the presently disclosed inventive concepts. Further, in the appended drawings, like or identical reference numerals or letters may be used to identify common or similar elements and not all such elements may be so numbered. The figures are not necessarily to scale and certain features and certain views of the figures may be shown as exaggerated in scale or in schematic in the interest of clarity and conciseness.

FIG. 1 is a schematic cross-sectional diagram of a semiconductor laser constructed in accordance with the presently disclosed inventive concepts wherein the semiconductor laser structure has a dielectric/metal cladding layer in substitution for a top semiconductor cladding layer.

FIG. 2 is a schematic cross-sectional diagram of a semiconductor laser of FIG. 1 disposed upon a substrate layer.

FIG. 3 is a schematic cross-sectional diagram of a semiconductor laser representative of certain embodiments of the presently disclosed inventive concepts.

FIG. 4 is a schematic cross-sectional diagram of a semiconductor laser representative of certain alternate embodiments of the presently disclosed inventive concepts.

FIG. 5 shows optical mode and refractive index profile along the growth direction of InAs-based IC lasers (a) with the top InAs plasmon cladding layer; (b) without the top InAs plasmon cladding layers. In the graph depicting the InAs-based IC lasers without the top InAs plasmon cladding layers, the thick line corresponds to an IC laser directly using metal (Ti/Au) as the top cladding; the thin line indicates an IC laser with a 200-nm-thick SiO₂, 20 -nm-thick Ti, and a 220-nm-thick Au layer as the top cladding. The inserts are the schematics of their waveguide structures, respectively.

FIG. 6 shows measured lasing spectra of a 15 μm wide and 1.25 mm long IC laser (denoted as A1) from wafer A operating in both cw (a) and pulsed (b) modes at different heat sink temperatures. The pulsed lasing spectra were shifted vertically for clarity.

FIG. 7 shows measured I-V-L characteristics of a 30 μm wide and 2.6 mm long IC laser (A2) from wafer A operating in both cw (a) and pulsed (b) modes at different heat sink temperatures.

FIG. 8 shows normalized lasing spectra of a 15 μm wide, 1.25 mm long laser (B1) made from wafer B operating in both (a) cw and (b) pulsed mode (1 μs pulse at 10 kHz) at different heat sink temperatures. The intensity of the lasing spectra is vertically shifted for clarity.

FIG. 9 shows measured pulsed I-V-L characteristics of a 20 μm wide, 1.25 mm long laser (B2) from wafer B operating in pulsed mode (1 μs pulses at 1 kHz) at different heat sink temperatures. Inset is the pulsed-mode lasing spectrum at 300 K (1-μs pulses at 10 kHz).

FIG. 10 shows measured I-V-L characteristics of a 20 μm wide, 1.25 mm long laser (B2) from wafer B operating in cw mode at different heat sink temperatures.

FIG. 11 shows threshold current density and voltage as a function of heat sink temperature for devices made from wafers A and B in both cw and pulsed modes. The extracted characteristic temperature T₀ for the best devices from wafers A and B are 46 and 49 K, respectively.

### DETAILED DESCRIPTION

Before describing various embodiments of the presently disclosed inventive concepts in more detail by way of exemplary description, examples, and results, it is to be understood that the presently disclosed inventive concepts are not limited in application to the details of methods and compositions as set forth in the following description. The presently disclosed inventive concepts are capable of other embodiments or of being practiced or carried out in various ways. As such, the language used herein is intended to be given the broadest possible scope and meaning; and the embodiments are meant to be exemplary, not exhaustive. Also, it is to be understood that the phraseology and terminology employed herein is for the purpose of description and should not be regarded as limiting unless otherwise indicated as so. Moreover, in the following detailed description, numerous specific details are set forth in order to provide a more thorough understanding of the disclosure. However, it will be apparent to a person having ordinary skill in the art that the presently disclosed inventive concepts may be practiced without these specific details. In other instances, features which are well known to persons of ordinary skill in the art have not been described in detail to avoid unnecessary complication of the description.

Unless otherwise defined herein, scientific and technical terms used in connection with the presently disclosed inventive concepts shall have the meanings that are commonly understood by those having ordinary skill in the art. Further, unless otherwise required by context, singular terms shall include pluralities and plural terms shall include the singular.

All patents, published patent applications, and non-patent publications mentioned in the specification are indicative of the level of skill of those skilled in the art to which the presently disclosed inventive concepts pertain. All patents, published patent applications, and non-patent publications referenced in any portion of this application are herein expressly incorporated by reference in their entirety to the same extent as if each individual patent or publication was specifically and individually indicated to be incorporated by reference.

All of the compositions and methods of production and application thereof disclosed herein can be made and executed without undue experimentation in light of the present disclosure. While the compositions and methods of the presently disclosed inventive concept have been described in terms of particular embodiments, it will be apparent to those of skill in the art that variations may be applied to the compositions and/or methods and in the steps or in the sequence of steps of the method described herein without departing from the concept, spirit and scope of the inventive concepts. All such similar substitutes and modifications apparent to those of skilled in the art are deemed to be within the spirit, scope and concept of the inventive concepts as defined herein.

As utilized in accordance with the methods and compositions of the present disclosure, the following terms, unless otherwise indicated, shall be understood to have the following meanings:

The use of the word “a” or “an” when used in conjunction with the term “comprising” in the claims and/or the specification may mean “one,” but it is also consistent with the meaning of “one or more,” “at least one,” and “one or more than one.” The use of the term “or” in the claims is used to mean “and/or” unless explicitly indicated to refer to alternatives only or when the alternatives are mutually exclusive, although the disclosure supports a definition that refers to only alternatives and “and/or.” The use of the term “at least one” will be understood to include one as well as any quantity more than one, including but not limited to, 2, 3, 4, 5, 6, 7, 8, 9, 10, 15, 20, 30, 40, 50, 100, or any integer inclusive therein. The term “at least one” may extend up to 100 or 1000 or more, depending on the term to which it is attached; in addition, the quantities of 100/1000 are not to be considered limiting, as higher limits may also produce satisfactory results. In addition, the use of the term “at least one of X, Y and Z” will be understood to include X alone, Y alone, and Z alone, as well as any combination of X, Y and Z.

As used in this specification and claim(s), the words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited elements or method steps.

The term “or combinations thereof” as used herein refers to all permutations and combinations of the listed items preceding the term. For example, “A, B, C, or combinations thereof” is intended to include at least one of: A, B, C, AB, AC, BC, or ABC, and if order is important in a particular context, also BA, CA, CB, CBA, BCA, ACB, BAC, or CAB. Continuing with this example, expressly included are combinations that contain repeats of one or more item or term, such as BB, AAA, AAB, BBC, AAABCCCC, CBBAAA, CABABB, and so forth. The skilled artisan will understand that typically there is no limit on the number of items or terms in any combination, unless otherwise apparent from the context.

Throughout this application, the term “about” is used to indicate that a value includes the inherent variation of error for the composition, the method used to administer the composition, or the variation that exists among the study subjects. Further, in this detailed description and the appended claims, each numerical value (e.g., temperature or time) should be read once as modified by the term “about” (unless already expressly so modified), and then read again as not so modified unless otherwise indicated in context. Also, any range listed or described herein is intended to include, implicitly or explicitly, any number within the range, particularly all integers, including the end points, and is to be considered as having been so stated. For example, “a range from 1 to 10” is to be read as indicating each possible number, particularly integers, along the continuum between about 1 and about 10. Thus, even if specific data points within the range, or even no data points within the range, are explicitly identified or specifically referred to, it is to be understood that any data points within the range are to be considered to have been specified, and that the inventors possessed knowledge of the entire range and the points within the range.

As used herein, the term “substantially” means that the subsequently described event or circumstance completely occurs or that the subsequently described event or circumstance occurs to a great extent or degree. For example, the term “substantially” means that the subsequently described event or circumstance occurs at least 90% of the time, or at least 95% of the time, or at least 98% of the time.

It has been newly discovered that certain problems with prior semiconductor lasers mentioned above can be circumvented and/or alleviated by using a hybrid waveguide structure such as shown and described herein. In at least one embodiment, the presently disclosed inventive concepts are directed to a semiconductor laser that is absent a top semiconductor optical cladding layer, devices constructed with such lasers, and methods of their use. Instead of having a top semiconductor cladding layer, the laser comprises a top optical cladding having one or more low refractive index dielectric layer and a thick outer metal layer. Typically, a dielectric layer has a refractive index lower than 2.0 (e.g., between 1.3 -2.0 or 1.4 to 2.0) and no more than 3.0. Thus, the refractive index of the dielectric layer will be between 1.3 to 3.0 or 1.4 to 3.0. The lower the refractive index of the one or more dielectric layer, the lower the amount of the optical wave that penetrates into the top optical cladding. Benefits of constructing the top optical cladding with the dielectric layer includes the weak absorption of light in the dielectric layer, and enhanced thermal conductivity (when using some dielectric materials such as Si₃N₄) as compared to some top semiconducting cladding layers. The top optical cladding can include multiple dielectric layers, rather than a single dielectric layer. In at least one embodiment, there is a thin (non-cladding) semiconductor contact layer between the dielectric layer and an upper separate confinement layer (SCL) of an active region of the laser. The SCL has a refractive index that is higher than the refractive index of the one or more dielectric material of the top optical cladding so as to accommodate portion of optical wave in the SCL. In addition, the refractive index of the SCL can be higher than the refractive index of the active region, such as when the active region includes a GaSb-based IC laser. The laser described herein has better optical confinement, reduced optical loss, and improved thermal dissipation with the higher output power as compared to lasers having a top semiconductor cladding layer.

Considering that long-wavelength IC lasers typically utilize ridge widths wider than 10 μm to minimize the surface recombination, the dielectric layer (e.g., constructed from SiO₂ or Si₃N₄) underneath the metal bonding pad can cover the majority of the laser ridge, while the metal contact to the ridge can be made to be only 1-3 μm. Herein it is shown that this dielectric layer, which is conventionally used for insulation and passivation of ridge waveguide lasers, also has properties that make it a favorable choice to form the top cladding of the laser waveguide. Typically, these materials have weak absorption in the mid-IR, and their large refractive index contrast with the active region (1.4 for SiO₂ versus ˜3.47 for the active region) makes the optical wave attenuate quickly in the cladding so that optical mode is more confined in the waveguide core region. Although the top metal layer directly on the ridge can introduce some optical loss, it is minimized with a narrow contact (e.g., 1-3 μm) that is significantly less than the laser ridge (e.g., ≦10 μm). Moreover, optical loss associated with mode leakage into the metal contact is significantly less in IC lasers, based on transverse electric (TE) modes, as compared to that in quantum cascade (QC) lasers, based on transverse magnetic (TM) modes. TE modes (unlike TM modes) are not coupled to lossy surface plasmon modes, and certain metals are actually suitable choices as cladding materials in the mid-IR. The insertion in the presently disclosed embodiments of a thin dielectric layer (with a small refractive index and low absorption losses), between semiconductor and metal layers, will decrease the optical field intensity that penetrates into the high loss metal cladding layers, thereby suppressing the optical waveguide loss. Thus, with the hybrid dielectric and metal top cladding layers described for the presently disclosed inventive concepts, a top semiconductor cladding layer is not necessary in IC lasers (and other types semiconductor lasers) described herein. In addition to the optical favorability of this approach, there are also several practical advantages such as simplified material growth and the ease to integrate distributed feedback gratings on top of the ridge.

The novel semiconductor lasers described herein have higher thermal conductivity than a conventional laser using a semiconductor superlattice (SL) cladding layer (which generally has a thickness in a range of 2-4 μm). This is because the one or more dielectric layer is thinner and its thermal conductivity is higher (for example, the thermal conductivity of Si₃N₄ is about 30 W/m.K, 10 times of that for InAs/AlSb SL). Furthermore, the top of a semiconductor laser is covered with a thick metal layer (having a thickness in a range of 1-8 μm and constructed of a material such as, but not limited to, Au, Ag, Cu, Ti/Au, WCu, and combinations thereof) so that the thermal dissipation of the laser is improved, resulting in higher continuous wave (cw) operating temperature and the higher output power. The top ridge of a semiconductor laser is generally relatively wide (>10 μm) so that the top metal contact is connected to the laser, in certain embodiments near the edge of its top surface. The width of the metal contact to the top surface of the semiconductor laser may be significantly narrower than the ridge width, which can be 1-2 μm wide for a narrow ridge (e.g. 15 μm) laser. For a broad-area laser such as 150 μm-wide laser, the metal contact width can be wider (e.g. 3-5 μm). The dielectric layer may be constructed of any dielectric material which functions in accordance with the present disclosure, such as but not limited to, Si₃N₄, AlN, Al₂O₃ SiC, and SiO₂. The semiconductor contact layer disposed between the dielectric layer and the SCL layer may be constructed of, for example, InAs, GaSb, InAsSb, GaInAs, or GaSbAs, and generally has a thickness (but is not limited to) in a range of 15-50 nm. The semiconductor contact layer is electrically coupled to the one or more metallic layer of the top optical cladding and serves as an electrical conduit between the active region and circuitry outside of the top optical cladding. The material forming the semiconductor contact layer may be doped to enhance the conductivity of the semiconductor contact layer. In some embodiments, the top optical cladding may include more than one dielectric material. For example, the top optical cladding may include two dielectric layers with each dielectric layer constructed of a different dielectric material. In certain instances, this may cause mixed interfaces between the two dielectric layers. Further, the dielectric materials can be single-crystalline or poly-crystalline materials.

As noted above, in the lasers of the presently disclosed inventive concepts, a top semiconductor layer which has a thickness sufficient to act as a cladding is absent, while the bottom semiconductor cladding layer is optionally retained. This bottom semiconductor cladding layer, when present, is, in certain embodiments, either an InAs/AlSb superlattice (SL) (or AlGaAsSb layer), for 3-4 μm wavelength lasers, or a heavily n-type doped InAs plasmon layer for longer wavelength lasers. In the presently disclosed hybrid waveguide structure, the majority of the top ridge is covered by a dielectric layer that has a refractive index (e.g., <3.0) which is much lower than a typical SL layer, while the metal contact to the semiconductor ridge can be made to be only 1-3 μm wide (in certain non-limiting embodiments) for minimizing optical loss. (The top ridge is typically wider than 10 μm to reduce surface recombination or achieve high output power.) Hence, the dielectric layer, typically placed in the center of the laser ridge, plays a role as the top optical cladding. As such, this hybrid-waveguide IC laser structure has lower optical loss than that in lasers having a top semiconductor cladding layer.

Also importantly, using a dielectric material having a thermal conductivity higher than a thermal conductivity of the conventional semiconductor cladding layer results in improved thermal dissipation. For example, a dielectric material, such as , Si₃N₄ (κ˜30 W/m·K) in combination with the top thick metal layer (such as, but not limited to, Au), results in improved thermal dissipation, much higher attainable output power, and improved device reliability. In this hybrid waveguide structure, the current is laterally injected through edge metal contacts and excellent injection is ensured with a large ratio between in-plane to vertical conductivity in the cascade region. Also, because transverse electric (TE) modes, unlike transverse magnetic (TM) modes, are not coupled to lossy surface plasmon modes, optical loss associated with mode leakage into the metal contact is significantly less in IC lasers based on TE modes, as compared to that in quantum cascade (QC) lasers based on TM modes. Furthermore, a metal contact placed near the edge of the ridge (or appropriately patterned on the top of the laser ridge) can be used to suppress higher-order lateral modes for manipulating and controlling the laser beam and mode selection. This suppression effect has been confirmed by the study of far-field patterns of plasmon-waveguide IC lasers. This beneficial feature results from the added flexibility associated with the absence of the top semiconductor cladding layer.

It should be understood that the semiconductor cladding layer previously has been considered to be essential to confine the optical wave generated in the waveguide core region that is typically composed of active region and SCLs, for which the refractive index of the cladding layer is lower than that of the waveguide core. Although the thickness of this kind of conventional semiconductor cladding layer is usually comparable to the lasing wavelength, its thickness can vary depending on specific requirements. For example, for distributed feedback (DFB) semiconductor lasers, the top semiconductor cladding layer can be significantly thinner than a wavelength (e.g., approximately ⅓ of a wavelength). However, such a thin cladding layer is still intended to confine (at least partially) the optical wave that is generated within the waveguide core and has a thickness sufficient to contain a substantial percentage (for example ≧1% and/or at least 1-25%) of the optical wave that is generated within the waveguide core in the top semiconductor cladding layer. Hence, such a cladding layer (i.e., able to contain ≧1% and/or at least 1-25% of the optical wave, and/or within a range of 1%-25%) will be considered herein to be a conventional optical cladding layer. Further, in some embodiments, a cladding layer made of semiconductor material that is configured to contain between 1% and no more than 30%, or no more than 35%, or no more than 40% or no more than 45% of an optical wave that is generated within the waveguide core will be considered herein to be a conventional optical cladding layer. The conventional semiconductor cladding layers are defined herein as different from other functional layers, such as the semiconductor contact layer. Usually, the semiconductor contact layer is heavily doped to reduce electrical resistance to a level in which the electrical resistance is negligible, and may have a refractive index that is lower than the refractive index of the waveguide core. Consequently, although it is thin (e.g., generally having a thickness in a range of 15-50 nm) and much shorter than the lasing wavelength, this contact layer may actually have a minor effect as an optical cladding layer in that the contact layer may contain a small amount (e.g., approximately 0.1%) of the optical wave. However, the semiconductor contact layer is defined herein to not be a semiconductor cladding layer because its purpose is for smoothing electrical connection not for containing the optical wave.

Because the present novel hybrid-waveguide semiconductor lasers are constructed without a top semiconductor cladding layer, the MBE growth of the lasers (such as IC lasers) is easier and less demanding, and their device performance in continuous wave (cw) operation is much better with significantly improved thermal dissipation, higher output power, reduced strain built-up and enhanced reliability, and increased flexibility for using patterned top metal layers for manipulating the laser beam and mode selection. In an alternative embodiment, the novel hybrid-waveguide IC lasers described herein are also constructed without a bottom semiconductor cladding layer, which can be done for example by removing the growth substrate and depositing another dielectric layer and metal cladding layer (similar to the top layers described above) on the exposed bottom face.

As noted above, the presently disclosed inventive concepts are directed to semiconductor lasers which in at least some embodiments have a top, non-semiconducting cladding comprising a dielectric layer and a thick metal layer, and a bottom cladding layer. The bottom cladding layer may be a high-doped semiconductor material. The laser also includes a waveguide core positioned between the top, non-semiconducting cladding and the bottom cladding layer. The waveguide core may include an active region. The active region may be constructed so as to generate light based on interband transitions. The light being generated based on interband transitions defines a lasing wavelength (or lasing frequency) of the laser. In at least one other embodiment the bottom cladding layer may comprise a high-doped semiconductor material for increasing the plasmon frequency of carriers in the semiconductor material so that the plasmon frequency of the semiconductor material is closer to the lasing frequency/wavelength of the laser. In alternate embodiments, as noted above, the laser may be constructed with a bottom dielectric layer as the bottom cladding layer rather than a bottom semiconductor cladding layer. The lasing wavelength (or lasing frequency) of the semiconductor lasers of the presently disclosed inventive concepts are typically in a range of from about 2.3 μm to about 20 μm.

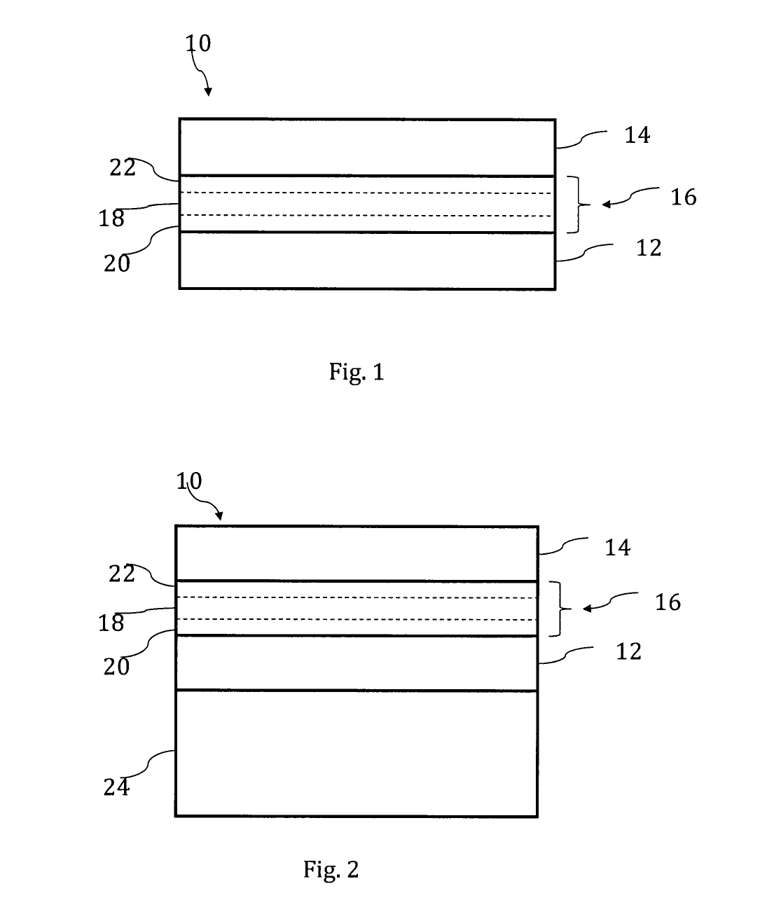

Referring now to the drawings, shown in FIG. 1 and designated by reference numeral 10 is a semiconductor laser constructed in accordance with the presently disclosed inventive concepts. The semiconductor laser 10 includes a bottom cladding 12, a top cladding 14, and a waveguide core 16 positioned between the bottom cladding 12 and the top cladding 14. The waveguide core 16 further includes an active region 18.

The top cladding 14 comprises a dielectric material configured as a dielectric layer, rather than a semiconductor material. The bottom cladding 12 may comprise a high-doped semiconductor material, or a dielectric material rather than a semiconductor material. In at least one embodiment, the active region 18 of the waveguide core 16 may be constructed so as to generate light based on interband transitions. The light being generated based on interband transitions in the active region 18 defines a lasing wavelength, or a lasing frequency of the semiconductor laser 10. The active region 18 can include an interband cascade region or other types of active regions. In certain embodiments the active region 18 is constructed so as to generate light based on interband transitions wherein the wavelength of the light is greater than about 2.0 μm.

The waveguide core 16 may be constructed to include a bottom separate confinement layer (SCL) 20 positioned between the active region 18 and the bottom cladding 12 to separate the active region 18 from the bottom cladding 12, and a top separate confinement layer (SCL) 22 positioned between the active region 18 and the top cladding 14 to separate the active region 18 from the top cladding 14. Although the bottom separate confinement layer 20 and the top separate confinement layer 22 are shown in FIG. 1 as being a single layer, it is to be understood that the bottom and top separate confinement layers 20 and 22 can be formed using a plurality of layers of materials, such as but not limited to, InAs, InAsSb, InGaAs, InGaAsSb, GaSb, GaInSb, AlGaSb, AlGaInSb, GaAs, AlInSb, AlSbAs, AlGaSbAs, or AlGaInSbAs, and combinations thereof As discussed above, the materials forming the bottom and top separate confinement layers 20 and 22 can be doped, low-doped, or non-doped.

Shown in FIG. 2 is schematic diagram of an particular embodiment of semiconductor laser 10 which includes bottom cladding 12, dielectric top cladding 14, waveguide core 16 comprising active region 18 and bottom and top separate confinement layers 20 and 22, respectively, such as shown in FIG. 1, which have been attached to a substrate 24 by any suitable method known in the art. For example, the layers may be deposited on the substrate 24 by molecular beam epitaxy (MBE), for example by growing the several layers of the semiconductor laser 10 upon the substrate 24, or by any other suitable deposition method. The substrate 24 may be made from a material such as, but not limited to, InAs, GaSb, GaAs, InP, Si, sapphire, and combinations thereof.

In another embodiment, the presently disclosed inventive concepts are directed to a method of forming the semiconductor laser 10 of FIG. 1 or 2. The bottom cladding 12 may be a layer that is grown (deposited), for example, on a substrate 24 that can be InAs or other suitable material as described herein. The bottom cladding 12 can be formed using a semiconductor material or one or more dielectric layer constructed of one or more dielectric material as noted above. The waveguide core 16 is grown upon the bottom cladding 12. The top cladding 14 is then grown on the waveguide core 16. In one embodiment the waveguide core 16 is grown using a MBE system on an n-type InAs substrate, for example. The semiconductor laser 10 may comprise an interband cascade region. The cascade region may comprise for example alternating active regions and injection regions in a manner well known to persons having ordinary skill in the art. Each active region and injection region pair forms an interband cascade stage that has a thickness, for example, but not limited to, of 495 Å. A cascade stage comprises many layers that are made of, for example, compound semiconductor materials InAs, Ga(In)Sb, AlSb with AlAs interfaces for balancing compressive strain from AlSb and Ga(In)Sb layers. For example, the thickness of each layer is specified and may be designed for lasing at ˜5.3 μm at a temperature of ˜300 K.

In at least one embodiment, these cascade stage regions are sandwiched by the bottom and top separate confinement layers 20 and 22, respectively, to form the waveguide core 16 discussed above that is sandwiched by the dielectric top cladding 14 and the bottom cladding 12. In one embodiment, the bottom cladding 12 may be formed using a high doped n-type InAs (semiconductor) material. For example the n-type InAs material may be heavily doped with Si up to 9×10¹⁸ cm⁻³. The bottom cladding 12 may be 1.5-μm thick, for example. The top cladding layer 14 comprises a dielectric material (as described elsewhere herein) having, for example, a thickness in a range of about 100 to about 600 nm. The top cladding 14 may further comprise a metal layer deposited upon the dielectric material and at least a portion of the metal layer may extend through the dielectric layer of top cladding 14 to be in electrical contact with the top separate confinement layer 22. The metal layer has, for example, a thickness in a range of about 1 to about 8 μm. Both the dielectric layer and metal layer together serve as the top cladding 14 to substantially confine the optical wave in the waveguide core 16.

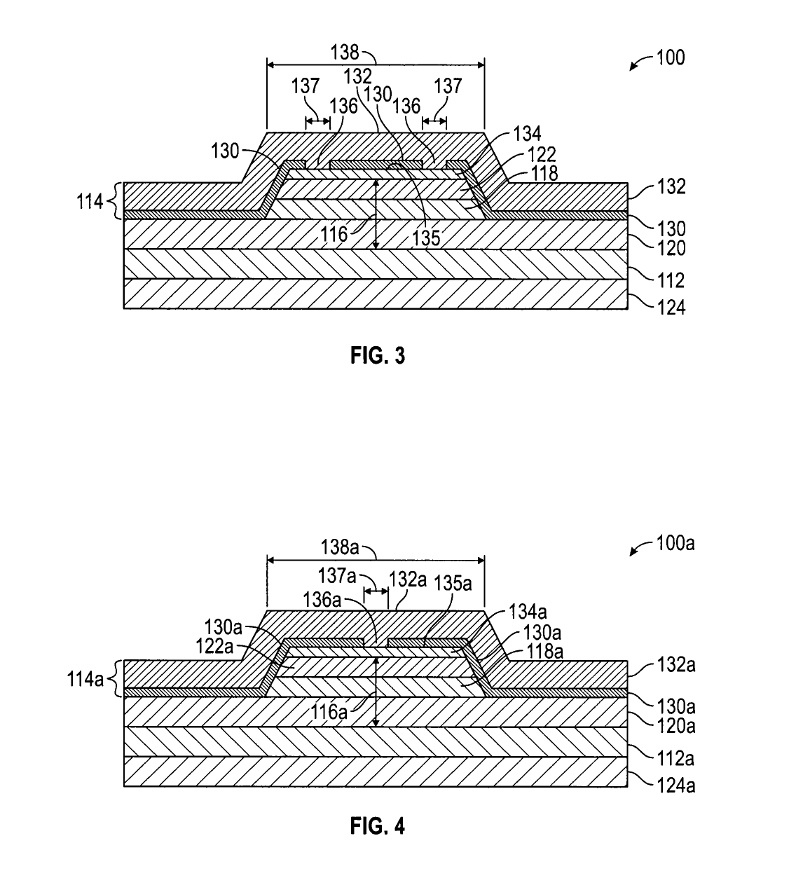

Shown in FIG. 3 and designated by reference numeral 100 is a schematic diagram of another embodiment of a semiconductor laser constructed in accordance with the presently disclosed inventive concepts. The semiconductor laser 100 includes a bottom cladding 112, a top cladding 114, and an active region 118 positioned between at least a portion of the bottom cladding 112 and at least a portion of the top cladding 114. The top cladding 114 comprises a dielectric material rather than a semiconductor material suitable for cladding. The bottom cladding 112 may comprise a high-doped semiconductor material, or a dielectric material rather than a semiconductor material. In at least one embodiment, the active region 118 may be constructed so as to generate light based on interband transitions. The light being generated based on interband transitions in the active region 118 defines a lasing wavelength, or a lasing frequency of the semiconductor laser 100. The active region 118 can include an interband cascade region or other types of active regions. In certain embodiments the active region 118 is constructed so as to generate light based on interband transitions wherein the wavelength of the light is greater than about 2 μm.

The active region 118 has a bottom separate confinement layer (SCL) 120 positioned between the active region 118 and the bottom cladding 112 to separate the active region 118 from the bottom cladding 112, and a top separate confinement layer (SCL) 122 positioned between the active region 118 and the top cladding 114 to separate the active region 118 from the top cladding 114. Together the active region 118, the bottom separate confinement layer 120, and the top separate confinement layer 122 make up a waveguide core 116 of the semiconductor laser 100. Although the bottom and top separate confinement layers 120 and 122 are shown as single layers, it is to be understood that the bottom and top separate confinement layers 120 and 122 can be formed using a plurality of layers of materials, such as but not limited to, InAs, InAsSb, InGaAs, InGaAsSb, GaSb, GaInSb, AlGaSb, AlGaInSb, GaAs, AlInSb, AlSbAs, AlGaSbAs, or AlGaInSbAs, and combinations thereof As discussed above, the materials forming the bottom and top separate confinement layers 120 and 122 can be doped, low-doped, or non-doped. The top cladding 114 of the semiconductor laser 100 further comprises a dielectric layer 130, a metal layer 132, and a semiconductor contact layer 134 positioned between the top separate containment layer 122 and at least a portion of the dielectric layer 130. The semiconductor contact layer 134 has a top surface 135 upon which the dielectric layer 130 and at least a portion of the metal layer 132 are disposed. The metal layer 132 comprises two metal contact strips 136 having widths 137 which extend through the dielectric layer 130 and are in electrical contact with the semiconductor contact layer 134 upon the top surface 135. The semiconductor laser 100 has a ridge width 138, which may be, but is not limited to 10 μm to 50 μm in certain embodiments. The bottom cladding 112 may comprise a semiconductor material suitable for cladding, or a dielectric material, as discussed elsewhere herein. The semiconductor laser 100 is optionally further disposed upon a substrate 124. The semiconductor laser 100 and component layers thereof may be constructed of the same materials as disclosed above for the embodiments of FIGS. 1 and 2, or other embodiments described herein, and may be constructed in a similar manner.

Shown in FIG. 4 and designated by reference numeral 100a is a schematic diagram of another embodiment of a semiconductor laser constructed in accordance with the presently disclosed inventive concepts, and which is similar in construction to the semiconductor laser 100 described above. The semiconductor laser 100a includes a bottom cladding 112a, a top cladding 114a, and an active region 118a positioned between at least a portion of the bottom cladding 112a and at least a portion of the top cladding 114a. The top cladding 114a comprises a dielectric material rather than a semiconductor material suitable for cladding. The bottom cladding 112a may comprise a high-doped semiconductor material, or a dielectric material rather than a semiconductor material. In at least one embodiment, the active region 118a may be constructed so as to generate light based on interband transitions. The light being generated based on interband transitions in the active region 118a defines a lasing wavelength, or a lasing frequency of the semiconductor laser 100a. The active region 118a can include an interband cascade region or other types of active regions. In certain embodiments the active region 118a is constructed so as to generate light based on interband transitions wherein the wavelength of the light is greater than about 2 μm.

The active region 118a has a bottom separate confinement layer (SCL) 120a positioned between the active region 118a and the bottom cladding 112a to separate the active region 118a from the bottom cladding 112a, and a top separate confinement layer (SCL) 122a positioned between the active region 118a and the top cladding 114a to separate the active region 118a from the top cladding 114a. Together the active region 118a, the bottom separate confinement layer 120a, and the top separate confinement layer 122a make up a waveguide core 116a of the semiconductor laser 100. Although the bottom and top separate confinement layers 120a and 122a are shown as single layers, it is to be understood that the bottom and top separate confinement layers 120a and 122a can be formed using a plurality of layers of materials, such as but not limited to, InAs, InAsSb, InGaAs, InGaAsSb, GaSb, GaInSb, AlGaSb, AlGaInSb, GaAs, AlInSb, AlSbAs, AlGaSbAs, or AlGaInSbAs, and combinations thereof. As discussed above, the materials forming the bottom and top separate confinement layers 120a and 122a can be doped, low-doped, or non-doped. The top cladding 114a of the laser 110a further comprises a dielectric layer 130a, a metal layer 132a, and a semiconductor contact layer 134a positioned between the top separate containment layer 122a and at least a portion of the dielectric layer 130a. The semiconductor contact layer 134a has a top surface 135a upon which the dielectric layer 130a and at least a portion of the metal layer 132a are disposed. The metal layer 132a comprises one metal contact strip 136a having a width 137a which extends through the dielectric layer 130a and is in electrical contact with the semiconductor contact layer 134a upon the top surface 135a.

The semiconductor laser 100a has a ridge width 138a, which may be, but is not limited to, 10 μm to 50 μm in certain embodiments. The bottom cladding 112a may comprise a semiconductor material suitable for cladding, or a dielectric material, as discussed elsewhere herein. The semiconductor laser 100a is optionally further disposed upon a substrate 124a. The semiconductor laser 100a and component layers thereof may be constructed of the same materials as disclosed above for the embodiments of FIGS. 1-3, or other embodiments described herein, and may be constructed in a similar manner.

In certain non-limiting embodiments, the dielectric layers 130 and 130a may have a thickness in a range of about 100 to about 600 nm, the metal layers 132 and 132a may have a thickness in a range of about 1 to about 8 μm, and the bottom cladding 112, when formed from a semiconductor material, may have a thickness in a range of about 1 μm to about 5 82 m thick for example. In certain embodiments, the widths 137 and 137a of the metal contact strips 136 and 136a, respectively, depend on the ridge width 138 and 138a, respectively. In lasers such as semiconductor laser 100 that have a pair of metal contact strips 136 and have ridge widths 138 of 20 μm, 30 μm, or 40 μm, the width 137 may be 3 μ, for example. In general, for lasers with larger ridge widths 138 and 138a, for example 150 μm, the widths 137 and 137a may be (but are not limited to) in a range of from about 3-5 μm, for example. When the laser has a more narrow ridge width 138 and 138a, for example 15 μm, the widths 137 and 137a, respectively, may be (but are not limited to) in a range of about 1-3 μm, for example. In general therefore, the width 137 and 137a of a semiconductor laser 100 and 100a, respectively, may be in (but are not limited to) a range of about 0.5 μm to about 7 μm. In certain embodiments, the metal contact strips 136 and 136a cover less than about about 30% (for example ≧1% to <30%) of the surface area of the top surface 135 and 135a of the semiconductor contact layers, 134 and 134a, respectively. In certain non-limiting embodiments, the semiconductor contact layers 134 and 134a have a thickness in a range of about 10 nm to about 100 nm, such as from about 15 nm to about 50 nm. In certain non-limiting embodiments, the bottom separate confinement layers 120 and 120a and top separate confinement layers 122 and 122a have thicknesses in a range of about 0.1 μm to about 2.5 μm. In certain non-limiting embodiments, the substrates 124 and 124a may have a thickness in a range of from about 100 μm to about 800 μm.

The semiconductor laser devices of the presently disclosed inventive concepts can be manufactured by any known process based on the description provided herein and knowledge known to those having ordinary skills in the art thus do not require undue experimentation for their implementation. The IC laser structure can be processed for example into deep-etched 150-μm-wide mesa-stripe and narrow (˜15 or 20 μm-wide) ridge laser devices, both with metal contacts on the top layer and bottom substrate. Laser bars can be cleaved to form 1.5 -mm to 2.0-mm-long cavities, with both facets left uncoated. The laser bars can be affixed, for example, with indium, epilayer side up, onto a copper heat-sink and then mounted onto the temperature-controlled cold finger of an optical cryostat for testing at temperatures of ≧80K.

The semiconductor lasers described herein may be used in a wide variety of devices and machines, including, but not limited to, tunable laser spectrometers, optical amplifiers, optical communication transmitters, optical active sensors, lidars, and optical illuminators.

### EXAMPLES

The presently disclosed inventive concepts, having now been generally described, will be more readily understood by reference to the following examples and embodiments, which are included merely for purposes of illustration of certain aspects and embodiments of the presently disclosed inventive concepts, and are not intended to be limiting. The following detailed examples of methods of use and construction of the presently disclosed inventive concepts and are to be construed, as noted above, only as illustrative, and not as limitations of the disclosure in any way whatsoever. Those skilled in the art will promptly recognize appropriate variations from the various structure, components, procedures and methods.

Described herein are embodiments of novel IC lasers of the presently disclosed inventive concepts which use dielectric and metal layers as the top cladding. In this example, the IC lasers have emission wavelengths near, for example, 5.3 μm. In this example, the novel lasers are compared to a laser with an InAs plasmon top cladding layer such as is previously known. Both the theoretical and experimental results show that the novel IC lasers having a top dielectric/metal waveguide cladding (absent a semiconductor cladding layer) have operating characteristics which are better than IC lasers constructed with a top semiconductor plasmon cladding layer. In this non-limiting example, the novel IC lasers with the hybrid dielectric/metal top cladding operated in pulsed mode up to 300 K with emission wavelength near 5.3 μm.

### Optical Waveguide and Device structures

A one-dimensional (1D) waveguide model based on the_transfer matrix method and a two-dimensional (2D) model using effective index method, were adopted to make a theoretical comparison of the different waveguide configurations. The optical constants of metals were defined in Rakic et al. (A. D. Rakic, A. B. Djurisic, J. M. Elazar, and M. L. Majewski, “Optical properties of metallic films for vertical-cavity optoelectronic devices”, Appl. Opt., vol. 37, pp. 5271-5283, 1998), and the dielectric constants for both nominally undoped and highly doped InAs were estimated from the Drude-Lorentz model using a theoretically evaluated doping-dependent effective mass (Y. B. Li, R. A. Stradling, T. Knight, J. R. Birch, R. H. Thomas, C. C. Phillips, and I. T. Ferguson, “Infrared reflection and transmission of undoped and Si-doped InAs grown on GaAs by molecular beam epitaxy”, Semicond. Sci Technol., vol. 8, pp. 101-111, 1993) and an empirical model for the doping-dependent mobility. In the calculation, optical absorption losses due to intersubband transitions and excess non-equilibrium carriers in the cascade region are not included. The results are not influenced by this, because the optimal mode profile is only weakly dependent on the absorption coefficient of the active region.

Two InAs-based IC laser structures, designated as wafer A and wafer B, were constructed for use in manufacturing lasers having different top waveguide configurations for initial analysis and comparison. The waveguide core of wafer A was composed of an active region sandwiched between a 1.15-μm-thick nominally undoped InAs bottom SCL, and a 1.15-μm-thick undoped InAs top SCL. The waveguide core of wafer B was composed of an active region sandwiched between a 1.10-μm-thick nominally undoped InAs bottom SCL, and a 1.45-μm-thick undoped InAs top SCL. The thicker top SCL in wafer B was used to reduce possible free-carrier loss introduced by the metal strips directly in contact with the top ridge. A 1.6-μm-thick n⁺⁺-type InAs (Si doped to 1×10¹⁹ cm⁻³) plasmon layer was used as the bottom cladding for both wafers A and B in this example.

Both wafer A and wafer B laser structures were constructed with nominally identical active regions comprising 10-stage interband cascade regions having a total thickness 0.56 μm. The refractive index of the cascade region was estimated to be 3.47 at 5.3 μm and 300 K. Wafer A was constructed to have a 1.6-μm-thick n⁺⁺-type InAs plasmon layer as a top waveguide cladding layer over the top SCL. Wafer B, the embodiment having the novel configuration described herein, was constructed to have a dielectric (SiO₂) layer and a metal (Ti/Au) layer as a top cladding over the SCL and also included a very thin (35 nm) n⁺⁺-type InAs semiconductor contact layer between the SCL of the active region and the dielectric/metal cladding. As noted elsewhere herein, this semiconductor contact layer, although comprising a semiconductor material, was too thin to serve as a cladding layer.

Wafers A and B were constructed to have similar configurations in several regards. For example, in reference to FIGS. 3 and 4, both wafers A and B were constructed with a bottom cladding , a top cladding , a waveguide core comprising a bottom SCL, an active region, and a top SCL positioned between at least a portion of the bottom cladding layer and at least a portion of the top cladding layer. In wafer A, a dielectric material served as an insulation layer and was covered by a metal layer which served to provide a current to the top cladding (via the semiconductor contact layer). The main distinction between wafer A and wafer B resided in the configuration and composition of the top cladding. In wafer A the top cladding (corresponding to layer 134 or 134a in FIGS. 3 and 4, respectively) comprised a semiconductor layer of sufficient thickness (e.g., 1.6 μm) that it could substantially contain an optical wave in the waveguide core. In wafer B, a semiconductor layer of sufficient thickness to substantially contain an optical wave in the waveguide core was absent. Instead, wafer B comprised a semiconductor contact layer (layer 134 or 134a in FIGS. 3 and 4, respectively) which could serve as an electrical contact between the waveguide core 116, 116a and the metal layer 132, 132a, respectively, but which was not of sufficient thickness to substantially contain an optical wave in the waveguide core 116, 116a.

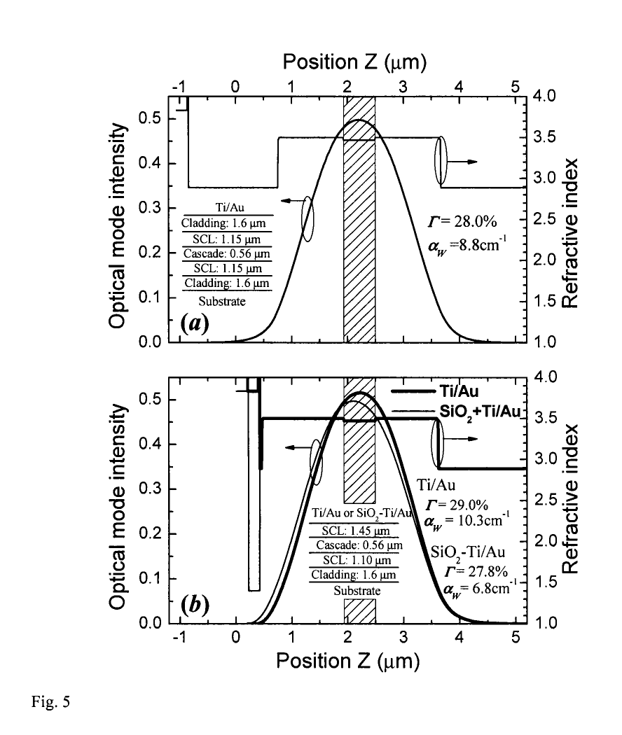

FIG. 5 shows a series of 1D optical mode profiles for different IC laser waveguide configurations. FIG. 5(a) shows the optical mode and refractive index profile of wafer A, which uses conventional n⁺⁺-InAs plasmon layers (semiconductor cladding layers) for both top and bottom claddings. For this configuration, the estimated confinement factor (Γ) and waveguide loss (α_{w}) were 28.0% and 8.8 cm⁻¹, respectively. FIG. 5(b) shows the theoretical results for wafer B under the assumption that the top cladding is composed of: (1) only Ti/Au and (2) a thin layer (200 nm) of SiO₂ followed by Ti/Au. The confinement factors and waveguide losses for configurations (1) and (2) are 29.0% and 27.8%, respectively and 10.3 cm⁻¹ and 6.8 cm⁻¹, respectively. The high loss for the purely metal-clad waveguide configuration is largely due to the poor optical properties of titanium, which, despite being very thin, introduces a significant amount of loss. However, in the hybrid dielectric-metal waveguide this loss is minimized by the use of narrow contacts for current injection. Based on theoretical estimates of the waveguide loss and confinement factor, it was found that the exemplary hybrid dielectric waveguide approach of the presently disclosed inventive concepts yields a device performance comparable or superior to a waveguide having InAs plasmon (semiconductor) cladding layers, by reducing the minimal gain required to reach threshold.

Other embodiments are constructed to alleviate the excessive loss introduced by Ti by introducing alternative materials. Table 1 shows the predicted effects of inserting a layer of silver or gold between the semiconductor and the Ti/Au contact. As shown, it is estimated that this approach reduces the waveguide loss by ˜1.2 cm⁻¹ at 5.3 μm.

TABLE 1
CALCULATED OPTICAL CONFINEMENT FACTOR AND
WAVEGUIDE LOSS OF IC LASERS AT A WAVELENGTH
OF 5.3 μm AT 300K.

| | | | Waveguide |
|---|---|---|---|
| | Top cladding | Confinement | loss |
| Wafer | configurations | factor (%) | (cm⁻¹) |
| A: InAs | Ti/Au | 28.0 | 8.8 |
| top | SiO₂—Ti/Au | 28.0 | 8.8 |
| plasmon | | | |
| layer | | | |
| B: no | Ag | 29.2 | 7.6 |
| InAs top | Au | 29.1 | 8.1 |
| plasmon | Ti/Au | 29.0 | 10.3 |
| layer | SiO₂—Au | 27.9 | 5.9 |
| | SiO₂—Ag | 27.9 | 5.7 |
| | SiO₂—Ti/Au | 27.8 | 6.8 |

The laser structures were grown using a Gen-II molecular beam epitaxy (MBE) system, equipped with group V crackers, on n⁺-doped (100) InAs substrates. In the non-limiting embodiments of the novel lasers described in the present example, the active region of the cascade stages comprised AlSb/InAs/GaInSb/InAs/AlSb coupled quantum wells (QWs) sandwiched between the electron and hole injectors, which are composed of InAs/AlSb and GaSb/AlSb QWs, respectively. The active region, along with the electron and hole injectors together form one cascade stage. Compared to previous plasmon-waveguide IC lasers, the electron injector is shorter with the first InAs QW width 6.1 nm, and the hole injector is enhanced with two QWs, for suppressing possible leakage current. The entire cascade-stage region is designed with AlAs and GaAs interfaces to achieve strain balance and enhance carrier confinement. It should be noted that the n-doping in the electron injector is low (˜1.5×10¹⁷ cm⁻³) for these IC lasers in contrast to the high n-doping recently reported for carrier rebalance in GaSb-based IC lasers.

After formation of the wafers, they were processed into ridge waveguide lasers, with ridge widths of 15 μm 20 μm, 30 μm, and 40 μm, by using contact photolithography and wet etching. A 200-nm-thick SiO₂ dielectric layer was deposited, narrow strips of the dielectric layer were opened to expose electrical contact on the top of the ridges, and Ti(20-nm thickness)/Au(220-nm thickness) metal contact layers were then deposited on the top and bottom of the thinned wafers. As noted above, the SiO₂ and Ti/Au layers also served as the top waveguide cladding (in place of an InAs plasmon layer) for devices made from wafer B. The laser with the 15-μm-wide ridge had one longitudinal 3 -μm wide top metal contact strip along the center and the lasers with 20, 30, and 40 -μm-wide ridges (similar to distributed feedback IC lasers) had two parallel 3-μm wide top metal contact strips near the two side edges of the ridge. These contacts are kept narrow in order to minimize the optical loss due to absorption in the metals, and ensure that the overall waveguide loss is close to the 1D value found for the hybrid dielectric/metal waveguide. To validate this, simulations for the 2D waveguides of these lasers were carried out using the effective refractive index method. The 2D waveguide simulations found that the confinement factor is essentially same for wafer A and wafer B, while the waveguide optical loss is lower for all ridge widths in wafer B (e.g., 7.4 cm⁻¹ for 20-μm-wide ridge and 6.9 cm⁻¹ for 30-μm-wide ridge) than in wafer A (8.8 cm⁻¹), consistent with expectations. However, the 15-μm-wide ridge laser from wafer B with the center metal contact would lase first on the first-excited lateral mode with a waveguide loss (7.0 cm⁻¹) that is lower than the waveguide loss (8.0 cm⁻¹) of the fundamental lateral mode. This results in a divergent double-lobe optical beam, making it difficult to effectively collect the optical output power from 15-μm narrow-ridge devices. Therefore optical output power measurements are only presented for 20- or 30-μm-wide laser devices.

The processed wafers were cleaved into laser bars with cavity lengths of 1-3 mm with both facets left uncoated, and then mounted epi-side-up on copper heat sinks for measurements. The optical power of the fabricated lasers was measured by a thermopile power meter for cw operation, and by a calibrated liquid-nitrogen cooled mercury-cadmium-telluride (MCT) detector in pulsed mode. A Nicolet Fourier transform infrared spectrometer was used to acquire the lasing spectra.

### Experimental Results

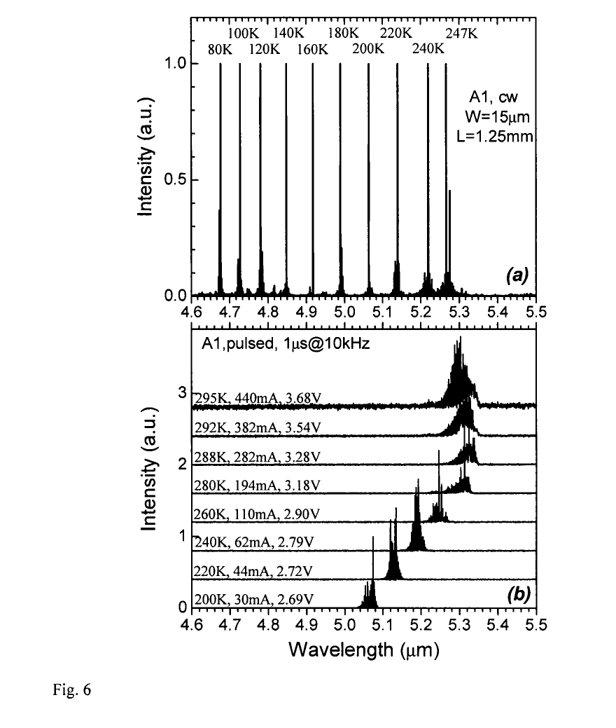

Devices made from wafer A (having n⁺⁺-InAs plasmon top cladding) are able to operate in both cw and pulsed modes at temperatures well above 220 K. FIG. 6 shows (a) cw and (b) pulsed lasing spectra from a 15-μm-wide and 1.25-mm long device (denoted as Al) that lased at temperatures up to 247 K near 5.27 μm in cw mode (a), and up to 295 K near 5.3 μm in pulsed mode (b). The maximum cw operating temperature of 247 K is higher than the 229K and 165 K reported for earlier IC lasers with superlattice (SL) cladding layers and similar low n-doped electron injectors at the comparable wavelengths of 5.1 and 5.4 μm, respectively. These earlier devices with SL cladding layers lased in pulsed mode at temperatures up to 295 K near 5.24 μm and 260 K near 5.7 μm, which are significantly higher than their maximum cw operating temperatures. This result corroborates an earlier suggestion that plasmon-waveguide IC lasers have better thermal dissipation than lasers based on SL cladding.

At 80 K, the threshold current density of this device is 18 A/cm² with a threshold voltage of 2.77 V, corresponding to a voltage efficiency of 96%. As shown in FIG. 6(a), as the temperature was changed, the emission wavelength (λ) was red shifted by 3.5 nm/K (from 4.67 μm at 80 K to 5.27 μm at 247 K) in cw mode. In pulsed mode, the lasing wavelength red shifted by 3.0 nm/K in the temperature range from 200 to 280 K, then red shifted at a reduced rate at higher temperatures before blue shifting slightly at the highest temperatures (FIG. 6(b)). The blue shift typically results from band filling effects that occur when the maximum operating temperature is being approached. The threshold current density of this device at 295 K in pulsed mode was 2.4 kA/cm².

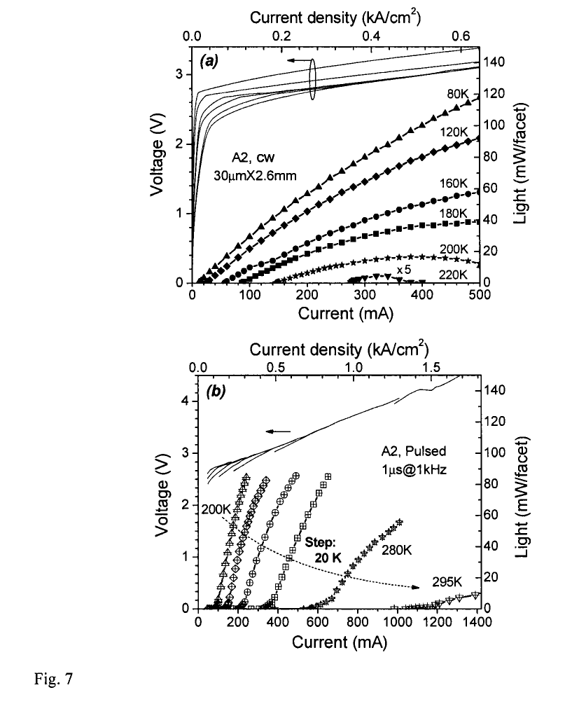

Shown in FIG. 7, a 30-μm-wide device (denoted as A2) lased in cw mode at temperatures up to 222 K, a lower maximum than that obtained from a 15 μm-wide device on the same bar, indicating more heating for the larger device. As shown from its current-voltage-light (I-V-L) characteristics (FIG. 7(a)), the cw output power of this 30-μm-wide device reached 120 mW/facet at 80 K and at 500 mA with a maximum wall-plug efficiency of ˜21% at 80 K. The output power and the wall-plug efficiency mentioned above are underestimated because correction was made only for the 10% transmission loss through the cryostat's optical window and not for losses from beam divergence. Based on simulated far-field patterns and the acceptance aperture of the power meter (diameter 19 mm), the estimated additional beam divergence loss is about 30%-43% (depending on laser size). Taking this correction into account the laser's actual output power exceeded 170 mW/facet and the wall-plug efficiency was about 30% at 80 K. In pulsed operation (1 μs pulses at 1 kHz), the device lased at heat-sink temperatures up to 295 K with a threshold current density around 1.3 kA/cm² and a threshold voltage of ˜4.0 V as shown in FIG. 7(b). The differential efficiency decreased with the temperature, but more rapidly for temperatures 280 K and above, which might be indicative of increased free-carrier absorption at high temperatures.

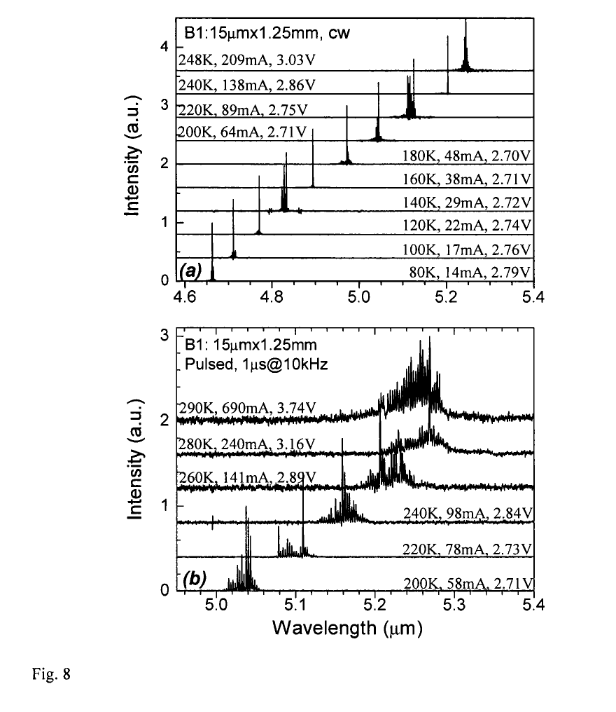

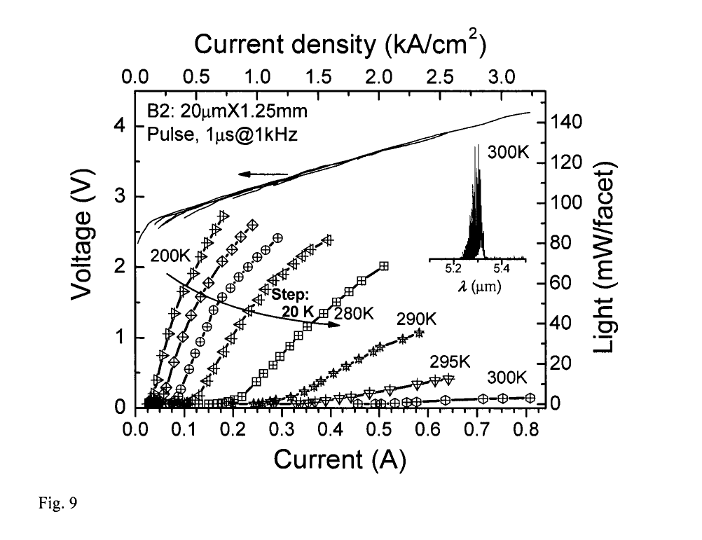

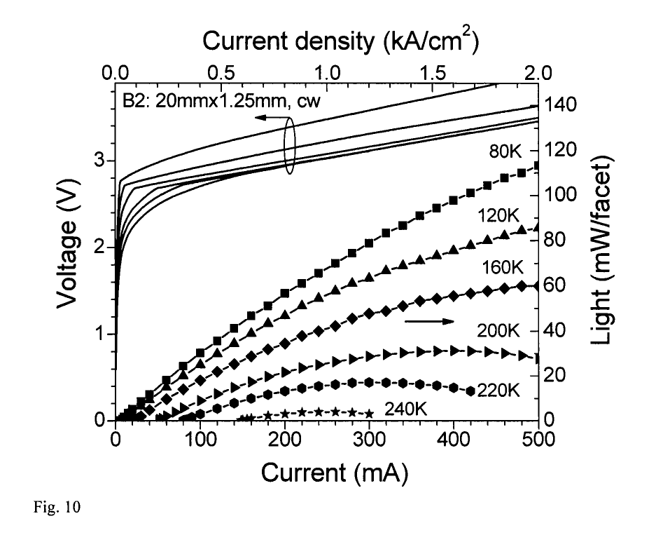

Lasers (of the presently disclosed inventive concepts) fabricated from wafer B (having the hybrid dielectric/metal layer only as the top cladding) showed device performance similar to (or slightly better than) lasers made from wafer A in terms of operating temperature. A 15-μm-wide and 1.25-mm-long device (device B1) lased in cw mode at temperatures up to 248 K near 5.25 μm with a threshold current density of 1.1 kA/cm² (see FIG. 8(a)). In pulsed operation (1 μs pulses at 10 kHz), the device lased at temperatures up to 290 K (see FIG. 8(b)), which is comparable to the maximum pulsed operating temperature (295 K) of device A1. A 20-μm-wide laser (device B2) from the same bar operated in pulsed mode at temperatures up to 300 K near 5.3μm with a threshold current density of 2.7 kA/cm², as shown in the insert of FIG. 9. The maximum pulsed operating temperature (300 K) of this 20-μm-wide device is slightly higher than that of devices from wafer A. This 20-μm-wide device lased in cw mode up to 245 K with a threshold current density of 1.0 kA/cm². At 80 K, device B2 also delivered a cw output power of 112 mW/facet with a threshold current density of ˜25 A/cm² and a threshold voltage of 2.77 V, as indicated by its I-V-L characteristics shown in FIG. 10. Again, the output power in FIG. 10 did not include the beam divergence losses.

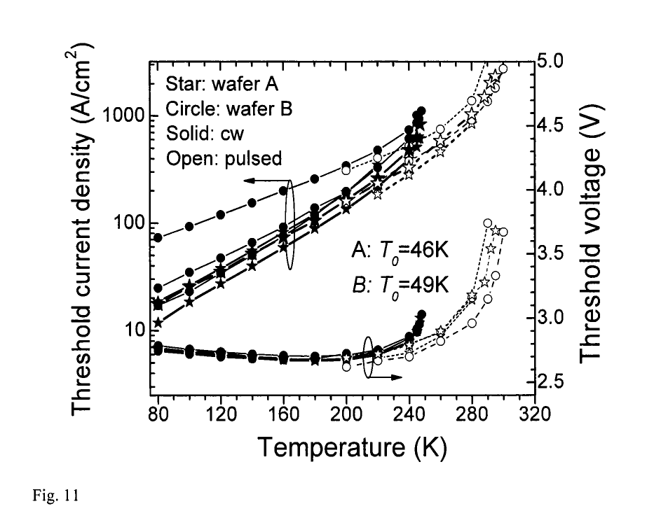

About 40 laser devices with various ridge widths and cavity lengths constructed from wafers A and B were tested and found to have near identical lasing wavelengths for a wide operating temperature range (80 to 290 K) with a temperature coefficient of ˜3.2 nm/K. The overall device performance was similar for lasers from wafers A and B (the novel lasers of the presently disclosed inventive concepts) in terms of output power, threshold current, and operating temperatures. The maximum pulsed operating temperature achieved in devices from wafer B is slightly higher than that from wafer A (300 K versus 295 K). The threshold current densities of devices from wafer A were generally lower compared to devices from wafer B, particularly at low temperatures, as shown in FIG. 11. The lowest threshold current density of 12 A/cm² at 80 K was obtained from a 15-μm-wide and 2.6-mm-long device from wafer A. One might attribute the somewhat larger threshold current densities in devices from wafer B to higher waveguide optical losses in wafer B devices compared to those from wafer A. If this were true, the maximum pulsed operating temperature achievable in devices from wafer B would be lower, which contradicts the experimental findings and modeling results. The difference in threshold current density between wafers A and B is more likely due to the higher surface-defect density of wafer B compared to wafer A, as indicated by optical microscope images. As seen in FIG. 11, the difference in threshold current density is most significant at low temperatures and becomes smaller at high temperatures. This supports the argument that material defects and processing variations are responsible for the threshold current difference because the defect-related Shockley—Read—Hall (SRH) recombination dominates at low temperatures. Similar defect effects were observed from early IC lasers and type-II SL detectors, and often occur for Sb-based devices due to material non-uniformity and processing variations. Such defects probably open up additional channels for leakage current. Consequently, in one embodiment, extra current is required to compensate for this carrier leakage channel in order to reach the lasing threshold in materials with high defect densities. These defects are unlikely to influence the modal gain and waveguide loss, which are the factors that ultimately determine the maximum pulsed-mode operating temperature of a laser (when heating effects can be neglected). Thus, the observed device performance is consistent with what is expected from defect-related leakage current and the similarity in measured maximum operating temperatures, and is supported by the theoretical calculations.

To further validate the present findings, two other IC laser structures (wafers C and D) were grown with waveguide structures similar to wafers A and B, respectively. Wafers C and D had the same 12-stage cascade region, but different top cladding configurations. Wafer C had a top InAs-plasmon (semiconductor) cladding layer and wafer D had only a thin (35 nm) n⁺⁺-type InAs contact (non-cladding) layer similar to the contact layer in wafer B (corresponding to layers 134 and 134a in FIGS. 3 and 4, respectively). They were processed into laser devices in the same way as wafers A and B. Measurements indicated that devices from wafers C and D were comparable, both lased in pulsed near 5.3 μm at room temperature. The maximum pulsed operating temperature achieved for devices from wafer D (no top semiconductor-plasmon cladding layer) is 315 K, which is slightly higher than the 310 K achieved for devices from wafer C. This result supports earlier findings.

In summary, in the present non-limiting example, InAs-based interband cascade (IC) lasers at 5.3 μm with different top waveguide cladding configurations were investigated both theoretically and experimentally. In accordance with the theoretical calculations, by replacing the top InAs-plasmon waveguide cladding with a dielectric-metal hybrid cladding, the IC lasers showed comparable or slightly superior device performances. This indicates the possible absorption loss from the contact metal was reduced because narrow metal contacts were used (and IC lasers are TE polarized) so that the dielectric layer (directly on the surface of the semiconductor ridge) plays the more significant role as the top waveguide cladding. Thus, a top semiconductor plasmon cladding layer is an optional component of the laser. This is a novel finding of the present work. Absence of such a semiconductor cladding layer is beneficial, especially for longer wavelength IC lasers, for which a thick cladding layer and a possibly high optical loss in semiconductor waveguides is undesirable and problematic. Other practical benefits include: (1) the MBE growth of the IC laser structure is simpler, including reduced growth time; and (2) without a top semiconductor cladding layer, a top distributed feedback (DFB) grating can be simply integrated with an IC laser for strong coupling.

The performance of the IC lasers described herein show significant improvement over previously known IC lasers with SL cladding layers and with similar low n-doped electron injectors operating at comparable wavelengths. The presently described novel lasers can also be constructed to use a carrier rebalancing in the cascade stage design wherein the InAs layers in the electron injector are highly doped with Si. The carrier rebalancing design enables cw operation of GaSb-based IC lasers above room temperature at mid-IR wavelengths (4.7-5.6 μm) with low-power consumption. The combination of the hybrid dielectric/metal waveguide described herein and the latest carrier rebalancing design over the cascade region will make it possible to extend room temperature, cw operation of IC lasers to longer IR wavelengths.

It will be understood from the foregoing description that various modifications and changes may be made in the various embodiments of the present disclosure without departing from their true spirit. For example, active regions and injection regions of the lasers can be constructed in a variety of manners and with various materials, and thicknesses of materials and layers. The description provided herein is intended for purposes of illustration only and is not intended to be construed in a limiting sense. Thus, while the presently disclosed inventive concepts have been described herein in connection with certain embodiments so that aspects thereof may be more fully understood and appreciated, it is not intended that the presently disclosed inventive concepts be limited to these particular embodiments. On the contrary, it is intended that all alternatives, modifications and equivalents are included within the scope of the presently disclosed inventive concepts as defined herein. Thus the examples described above, which include particular embodiments, will serve to illustrate the practice of the presently disclosed inventive concepts, it being understood that the particulars shown are by way of example and for purposes of illustrative discussion of particular embodiments of the presently disclosed inventive concepts only and are presented in the cause of providing what is believed to be a useful and readily understood description of procedures as well as of the principles and conceptual aspects of the inventive concepts. Changes may be made in the formulation of the various components and compositions described herein, the methods described herein or in the steps or the sequence of steps of the methods described herein without departing from the spirit and scope of the presently disclosed inventive concepts.

What is claimed is:

1. A semiconductor laser, comprising:
a waveguide core comprising an active region configured to generate light based on interband transitions, the light having a lasing wavelength;
a top cladding positioned above the waveguide core, the top cladding comprising a dielectric layer and a metal layer, the metal layer having a thickness of at least about 1 μm and comprising at least one contact strip, and wherein the top cladding is absent a semiconductor material that (1) has a refractive index which is less than a refractive index of the waveguide core, and (2) is configured to contain at least 1% of an optical wave that is generated within the waveguide core; and
a bottom cladding positioned below the waveguide core.

2. The semiconductor laser of claim 1, wherein the top cladding is absent a semiconductor material that is configured to contain at least 1%-25% of the optical wave that is generated within the waveguide core.

3. The semiconductor laser of claim 1, wherein the top cladding is absent a semiconductor material that is configured to contain a portion of the optical wave within the waveguide core, wherein the portion is in a range of 1%-25% of the optical wave that is generated within the waveguide core.

4. The semiconductor laser of claim 1, wherein the waveguide core further includes a top separate confinement layer positioned between the active region and the top cladding and a bottom separate confinement layer positioned between the active region and the bottom cladding, the top and bottom separate confinement layers each comprising one or more layers of a semiconductor material.

5. The semiconductor laser of claim 4, wherein the semiconductor material forming the top and bottom separate confinement layers is selected from the group consisting of InAs, InAsSb, InGaAs, InGaAsSb, GaSb, GaInSb, AlGaSb, AlGaInSb, GaAs, AlInSb, AlSbAs, AlGaSbAs, and AlGaInSbAs.

6. The semiconductor laser of claim 1, wherein the active region further includes an interband cascade region.

7. The semiconductor laser of claim 1, wherein the active region of the waveguide core comprises one or more semiconductor layers selected from the group consisting of InAs, InAsSb, InGaAs, InGaAsSb, GaSb, GaInSb, AlGaSb, AlGaInSb, GaAs, AlSb, AlAs, AlInSb, AlSbAs, AlGaSbAs, and AlInGaSbAs.

8. The semiconductor laser of claim 1, wherein the lasing wavelength is in a range of about 2 μm to about 20 μm.

9. The semiconductor laser of claim 1, further comprising a semiconductor contact layer between at least a portion of the dielectric layer and the waveguide core, the semiconductor contact layer having a top surface, wherein the semiconductor contact layer is configured to contain less than 1% of the optical wave that is generated within the waveguide core.

10. The semiconductor laser of claim 9, wherein the at least one contact strip comprises an area less than 30% of the top surface of the semiconductor contact layer.

11. The semiconductor laser of claim 9, wherein the semiconductor contact layer is configured to contain less than 0.1% of the optical wave that is generated within the waveguide core.

12. The semiconductor laser of claim 9, wherein the semiconductor contact layer has a thickness in a range of 15-50 nm.

13. The semiconductor laser of claim 1, wherein the dielectric layer has a thickness in a range of 100- 600 nm.

14. The semiconductor laser of claim 1, wherein the dielectric layer has a refractive index between 1.3to 3.0.

15. The semiconductor laser of claim 1, wherein the dielectric layer comprises at least one of Si₃N₄, AlN, Al₂O₃, SiC, and SiO₂.

16. The semiconductor laser of claim 1, wherein the bottom cladding comprises a dielectric layer and a metal layer, and wherein the bottom cladding is absent a semiconductor material that (1) has a refractive index less than the refractive index of the waveguide core and (2) is configured to contain at least 1% of an optical wave that is generated within the waveguide core.

17. The semiconductor laser of claim 1, wherein the bottom cladding comprises a semiconductor material that (1) has a refractive index lower than the refractive index of the waveguide core and (2) is configured to contain at least 1% of the optical wave that is generated within the waveguide core.

18. The semiconductor laser of claim 1, comprising a substrate selected from the group of materials consisting of InAs, GaSb, GaAs, InP, Si, sapphire, and combinations thereof.

19. The semiconductor laser of claim 1, wherein the metal layer has a thickness in a range of at least about 1 μm to about 8 μm.

20. The semiconductor laser of claim 1, wherein the metal layer comprises at least one of Ag, Au, Cu, TiAu, and WCu.

21. A device comprising the semiconductor laser of claim 1, wherein the device is selected from the group consisting of tunable laser spectrometers, optical amplifiers, optical communication transmitters, optical active sensors, lidars, and optical illuminators.

22. A method of causing an emission of an optical wave, comprising:
injecting an electric current into a semiconductor laser, the semiconductor laser comprising:
a waveguide core comprising an active region configured to generate light based on interband transitions, the light having a lasing wavelength;
a top cladding positioned above the waveguide core, the top cladding comprising a dielectric layer and a metal layer, the metal layer having a thickness of at least about 1 μm and comprising at least one contact strip, and wherein the top cladding is absent a semiconductor material that (1) has a refractive index which is less than a refractive index of the waveguide core, and (2) is configured to contain at least 1% of an optical wave that is generated within the waveguide core; and
a bottom cladding positioned below the waveguide core;
whereby an optical wave is emitted from the semiconductor laser.
